(19) United States
(12) Patent Application Publication
(10) Pub. No.: US 2014/0000690 A1
(43) Pub. Date: Jan. 2, 2014

(54) Intrinsically Semitransparent Solar Cell and Method of Making Same

(71) Applicants: Victor V. Plotnikov, Toledo, OH (US); Chad W. Carter, Toledo, OH (US); John M. Stayancho, Marblehead, OH (US); Alvin D. Compaan, Holland, OH (US)

(72) Inventors: Victor V. Plotnikov, Toledo, OH (US); Chad W. Carter, Toledo, OH (US); John M. Stayancho, Marblehead, OH (US); Alvin D. Compaan, Holland, OH (US)

(21) Appl. No.: 14/004,272

(22) PCT Filed: Mar. 15, 2012
(86) PCT No.: PCT/US12/29214

§ 371 Date: Sep. 10, 2013

Related U.S. Application Data
(60) Provisional application No. 61/465,155, filed on Mar. 15, 2011.

(51) Int. Cl. H01L 31/02

(52) U.S. Cl. CPC H01L 31/02021
USPC 136/255; 136/256; 438/98

(57) ABSTRACT

An intrinsically semitransparent photovoltaic cell and module are described and a method for fabricating the same. Key steps in the fabrication involve the use of magnetron sputtering under appropriate conditions, the deposition of ultra-thin semiconductor absorber layers, and the fabrication of a transparent back contact.

### CROSS REFERENCE TO RELATED APPLICATIONS

This application claims the benefit of U.S. Provisional patent application Ser. No. 61/465,155 filed Mar. 15, 2011.

### FIELD OF THE INVENTION

The present invention relates generally to photovoltaic cells and the detailed layer structure thereof. More specifically, the present invention relates to the structure of a thin-film PV cell that is intrinsically semitransparent and the method of making such a device including control of the transmitted light color or spectrum and control of the reflected light color or spectrum.

### BACKGROUND OF THE INVENTION

The vast majority of photovoltaic devices or solar cells are fully opaque so that essentially all light incident on the cell is absorbed by the cell or module. Maximizing the light absorption will maximize the power generated by the solar cell. However, in some applications it is desired to use the PV device in an arrangement that allows some of the light to pass through the device, such as in a window, skylight, or canopy. There are a number of module structures in which some light transmission has been obtained by spacing the cells such that light passes between individual cells in a module (e.g., wafer silicon modules) There are other structures that use thin-film PV in which some of the PV coating has been removed, such as by laser scribing or chemical etching. These solutions have the significant disadvantage of yielding a spatially non-uniform light transmission which is often undesirable.

There are some other thin-film PV materials that offer partial light transmission without such spacing of cells or selective removal. These are organic PV (small molecule or polymer) and dye sensitized solar cells (DSSC) which have relatively narrow absorption bands that absorb strongly in some spectral regions and weakly in others. This yields light transmission that is highly colored and also poor PV efficiency because only a narrow band of the visible spectrum is absorbed.

### SUMMARY OF THE INVENTION

The present invention relates generally to PV cells and methods of fabrication thereof. More particularly, this invention relates to a PV cell having an absorber layer sufficiently thin but uniform and pinhole free so as to be semitransparent but still to have high efficiency as a solar cell or module. This invention also identifies a suitable transparent back contact that functions well with the preferred embodiment. Finally, the present invention also discloses the method of manufacturing such a semitransparent PV device.

### BRIEF DESCRIPTION OF THE DRAWINGS

FIG. 1 is a side perspective view of a layer structure of thin-film solar cell of the present invention.

FIG. 2a is an SEM micrograph cross section of CdTe sputter deposited under conditions suitable for ultra-thin PV.

FIG. 2b is an SEM micrograph cross section of CdTe sputter deposited under conditions unsuitable for ultra-thin PV.

FIG. 3 is a side elevation view of a magnetron sputter deposition chamber with plasma.

FIG. 4 is a graph showing current density vs. voltage curves showing the performance of ultra-thin CdTe solar cells grown by magnetron sputtering.

FIG. 5 is a table showing the performance parameters of ultra-thin CdTe solar cells with open circuit voltage (V_{oc}), short circuit current (J_{sc}), fill factor, and efficiency for air mass 1.5 global (Eff).

FIG. 6 is a front elevation photograph of a prototype monolithically integrated PV module.

FIG. 7a is a partial side view of a monolithic interconnect scheme using laser scribing to minimize the dead area and maintain clean visual appearance.

FIG. 7b is a partial side view of a monolithic interconnect scheme using laser scribing with insulating ink backfill of the P1 scribe.

FIG. 8 is a graph showing monthly and annual AC energy produced for 1 kW arrays deployed in NYC. Top curve is the sum of three arrays. Data from PV Watts.

FIG. 9a is a cross sectional view of a back contact layer of the present invention.

FIG. 9b is a cross sectional view of another feature of a back contact layer.

### DETAILED DESCRIPTION OF THE PREFERRED EMBODIMENT(S)

The present invention utilizes an inorganic semiconductor, such as CdTe, that has a very broad absorption spectrum, e.g., spanning the entire visible spectrum. In the present invention the transparency is accomplished by thinning the semiconductor layers sufficiently to achieve partial transparency and using specially developed structures for the front and back electrodes that are also transparent. This is the first time such a structure with high efficiency has been developed successfully using inorganic materials. The fabrication methods of such a structure are identified here. The features of the invention will be more readily understood by reference to the attached drawings in connection with the following description.

In order to make a solar cell that inherently transmits some of the light incident on it while utilizing most of the light to generate current and voltage in the solar cell, it is necessary to fabricate extremely thin layers that have a thickness of the order of the absorption length (1/absorption coefficient). For the case of cadmium telluride (CdTe) this requires a thickness of about 100 nm to about 750 nm with a thickness from about 250 nm to about 500 nm being preferred. In addition, alloys of CdTe, such as CdZnTe can also be used in this invention. For the case of cadmium sulfide (CdS) the thickness of this layer would be from about 30 nm to about 120 nm. Such thin layers that are also free of pinholes are difficult to fabricate by most methods. For example, close spaced sublimation (CSS) and vapor transport deposition (VTD), commonly used for CdTe layer deposition, exhibit large densities of small void spaces or pinholes so that when the thickness is less than about 1500 nm, these non-uniformities cause severe shunting of the solar cell which becomes increasingly severe for thin layers. These shunting problems are aggravated as the area increases toward large PV modules with size of 1 square meter or larger. Thus it is critically important to be able to deposit the semiconductor layers with extremely low density of pinholes and other non-uniformities. In the present invention, we show how this can be done by choosing carefully the magnetron sputter deposition parameters.

Another critically important issue for achieving transparent thin-film PV structures is that all other layers of the cell or module must also be transparent. This includes a transparent conductor or transparent conducting oxide (TCO) used in most cells and modules. It also includes a high resistivity transparent (HRT) layer also used in many thin-film cells and modules. The HRT layer can be positioned between the TCO and semiconductors. An HRT or other buffers can also be positioned between the semiconductors and the back contact or back conductive electrode layer (BC). The HRT or buffer layers can be used to reduce the effects of any pinholes or weak diodes on the performance of the solar cell. The HRT or buffer layers can also be used to adjust the energy band alignments to facilitate electron and hole transport across the interface between layers of the solar cell. But significantly, it also includes a transparent back contact on the far side of the cell or module that is spaced farthest from the sun. Here we identify materials and fabrication processes needed for such a transparent back contact (BC) for the preferred embodiment, the semitransparent CdS/CdTe solar cell and module.

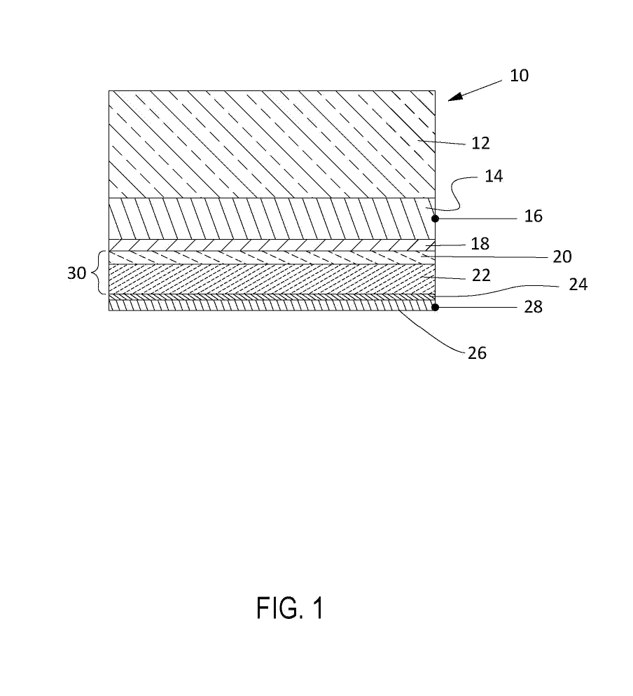

Referring now to the drawings, FIG. 1 illustrates the structure of a thin-film CdTe solar cell. This has all of the previously identified layers shown in U.S. Pat. No. 7,141,863 of Compaan and Gupta but in addition shows an HRT layer as has been discussed in the literature. The teaching of U.S. Pat. No. 7,141,863 is specifically incorporated by reference into this application. The teaching of U.S. Pat. Nos. 6,852,614 and 5,393,675 are specifically incorporated by reference into this application. We disclose the conditions necessary for the sputter deposition process that will result in suitable materials quality for the semiconductor layers, primarily the absorber layer that can optimize the performance of an ultra-thin solar cell. By “ultra-thin” we refer to thicknesses of semiconductor for which some visible light can penetrate through the layer. In the case of CdTe this requires about 750 nm or less. The appropriate thickness limit will depend on the details of the application and the absorption coefficient of the absorber semiconductor. For example, the ternary semiconductor, CIGS (copper-indium-gallium diselenide) may require thickness less than 200 nm because its absorption coefficient is significantly higher than CdTe over the visible spectral range.

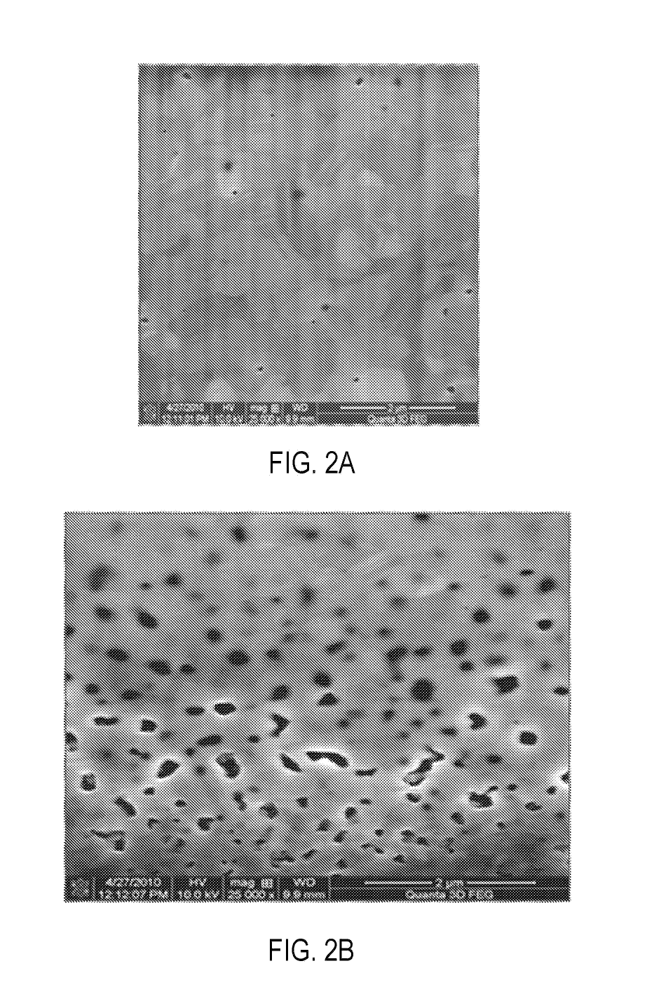

In order to obtain a high performance solar cell/module with ultra-thin absorber layers, it is necessary to deposit a very dense film that is essentially free of pinholes or voids. This presents a serious limitation to conventional deposition methods such as vapor transport deposition and close spaced sublimation or vacuum evaporation. Magnetron sputter deposition when performed under suitable conditions can provide such high quality, dense films. An example is presented in FIG. 2a which shows a 3 degree bevel cross-sectional electron micrograph of a sputter deposited film. The sample was prepared by low incidence surface milling with a focused ion beam (FIB). This is an example of the materials quality that can be achieved with sputter deposition. Even in the case of magnetron sputtering, some deposition conditions are not suitable for achieving suitable materials quality for ultra-thin absorbers, after the full cell or module processing is complete. An example of an unacceptable ultra-thin absorber is shown in FIG. 2b.

The sputter deposition process can be optimized to provide deposition conditions that are especially well suited to depositing very uniform coatings on moderately curved surfaces, such as surfaces for auto sunroofs. This is explained below.

Earlier work by Compaan, et al. demonstrate/claim that magnetron sputtering, when performed under suitable conditions (gas pressure, rf or dc power, substrate heating) permits high performance coatings suitable for high efficiency thin film solar cells with the substrate held at relatively low temperatures. For example, sputtering can be done at ˜250° C. compared with temperatures for thermal evaporation, closed space sublimation, or vapor transport deposition which are 550° C. to 600° C. In practice it has been found that the sputtering process can be conducted from about 150° C. to about 350° C. with the preferred application being less than 250° C. Lower temperature deposition is possible because of the additional kinetic energy coming to the growth surface from the energetic atoms and ions during sputtering. This has the effect of increasing the surface adatom mobility over that which occurs with thermal activation alone, that is, without the sputter plasma assist. The extra kinetic energy of the incoming atoms (either the argon sputter gas atoms or the sputtered atoms such as Cd, Te, or S) helps to enhance the mobility of atoms on the growth interface so that the atoms find the lowest energy locations which are usually the best crystallographic positions.

The sputter gas pressure is important in determining how many collisions an atom sputtered from the target will undergo before reaching the growth interface. For RF sputtering the sputtered atoms have initial kinetic energies from a few electron volts (eV) to some tens of eV. Removing some of this initial kinetic energy through collisions is important to avoid damage to the growing semiconductor film. The mean free path (mfp) between collisions is given by kinetic theory which shows that for a gas temperature of 100° C. and argon gas pressure of 10 milliTorr (mTorr), the mfp is about 2 cm. We find that the optimum pressure for sputtering the ultra-thin layers of CdTe is in the range where there are approximately 1 to 3 collisions before reaching the film growth interface. For a substrate 10 cm from the sputter target, a pressure of 5 mTorr gives about 2-3 collisions when the gas kinetic temperature is about 100° C. (Larger target-to-substrate distances would require lower gas pressure for optimum film growth, and vice versa.) Higher pressures reduce the sputtered atom kinetic energy too much, scatter atoms away from the substrate and lower the deposition rate. Lower pressures produce too much ion bombardment of the growing film which is undesirable for CdTe and related absorber materials. For the materials of the semiconductor junction, especially CdTe, we require the lowest possible defect density and void density. These are best obtained with Ar sputter gas pressure in the range of 3-50 mTorr and preferably in the range of 5-15 mTorr. Ar gas purity is important and best results are obtained with 99.999% pure argon.

If the kinetic energy of the atoms at the growth surface is only due to the temperature of the substrate, then the best film properties are usually obtained at the highest possible temperatures where the adatoms have their highest mobility. This typically is limited by the softening point of the glass or to about 600° C. for soda-lime glass. Even higher temperatures have been used with borosilicate glass and other glass formulations with higher melting points. This is part of the reason that most record efficiency CdS/CdTe cells have used these special glass compositions.

When growth is performed at high temperatures, the film growth rate is a delicate balance between the incoming growth flux from the source and the reverse sublimation rate from the film. The sublimation rate from the film is exponentially sensitive to the inverse of the substrate temperature:

Sublimation rate=constant×T^{1/2}exp(−Ea/kT), where Ea is the activation energy for sublimation.

Consequently, small variations in temperature, which are highly likely with curved substrates, will produce large changes in sublimation rate and consequently large variations in the net growth rate. Since sputter growth can be done at much lower substrate temperatures, this variation in sublimation rate across a substrate due to small variations in substrate temperature is much less of a problem. The consequence is that sputter deposition facilitates more uniform films across the entire substrate even with curved substrates and with some variation in temperature.

Traditional thin-film PV, including CdTe-based modules, are not very sensitive to variations in the film thickness, since the cell performance is only weakly dependent on the CdS or CdTe thicknesses. However with semitransparent, ultra-thin CdTe modules, the light transmission is very sensitive to the thickness of the CdTe in the range below 750 nm where significant light transmission occurs. Therefore, it is very important for transparent PV applications to be able to control the layer thickness with extreme accuracy.

We claim that magnetron sputter deposition provides the required control of thickness that can yield very uniform films even over curved surfaces. The control is sufficient to avoid noticeable variations on light transmission through different regions of a curved glass piece such as an auto sunroof.

It should be recognized that the deposition process must achieve appropriate doping levels in the semiconductors, excellent composition control, high quality grain structure, and good grain boundary passivation in order to yield high efficiency devices. These requirements are met by sputtering under appropriate conditions as described previously.

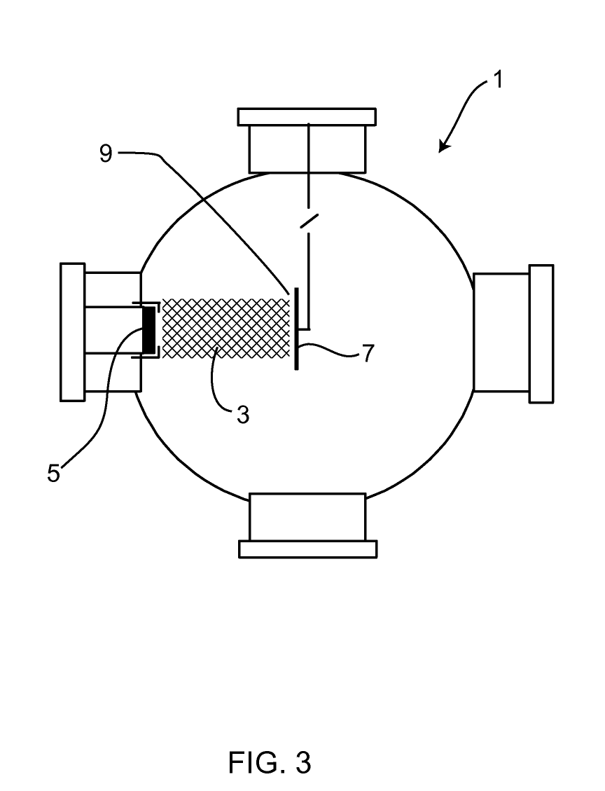

FIG. 3 illustrates the geometry of a typical sputtering process in deposition chamber 1. The plasma 3 between the sputter target 5 and the substrate 7 on which the film is growing is critically important in the growth process. There is a “substrate sheath” 9 with an electric potential difference between the plasma and the substrate. The plasma potential must be suitably positive relative to the substrate so that low energy positive ion bombardment of the growth interface occurs. This ion and some electron bombardment play a key role in the growth of dense and uniform absorber layers suitable for ultra-thin, semitransparent PV.

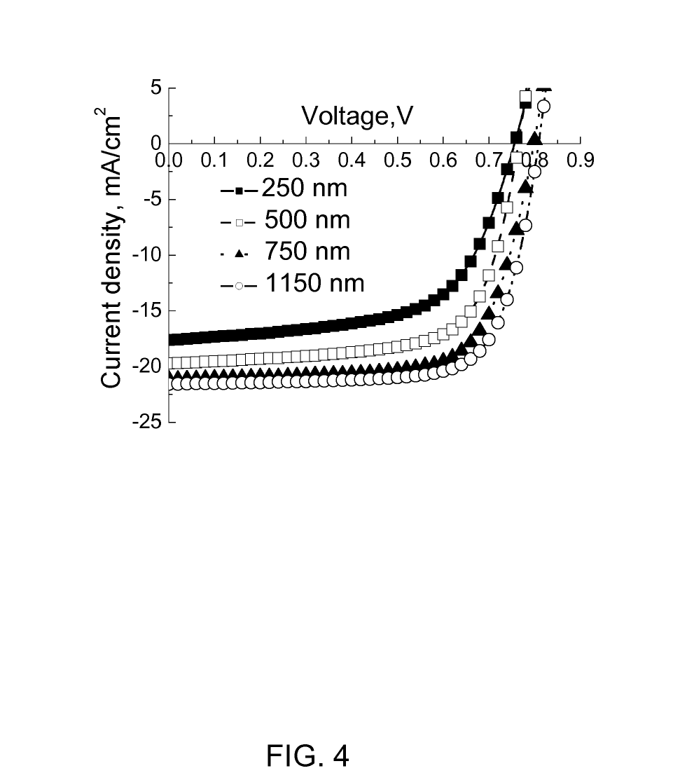

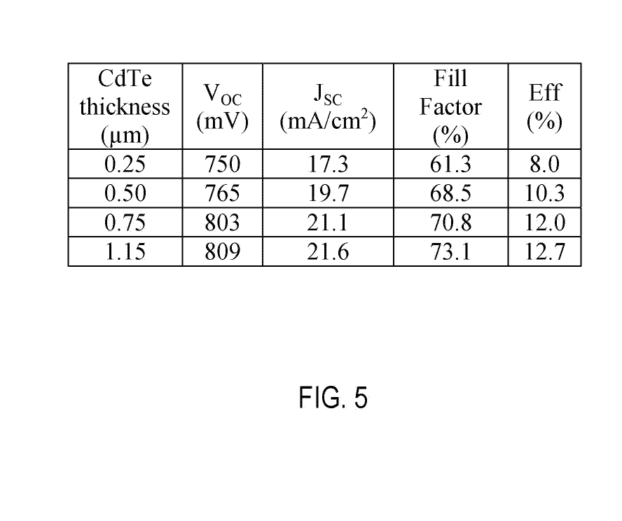

The performance of small CdS/CdTe solar cells over a range of absorber thicknesses is shown in FIG. 4. The full J-V curves are given in FIG. 4 and the typical cell performance parameters are shown in FIG. 5 including open circuit voltage (V_{oc}), short circuit current density (J_{sc}), fill factor (FF), and efficiency. These data demonstrate the viability of the sputter process under suitable conditions. The data show proof of the performance with ultra-thin CdTe layers.

Referring to FIG. 1 for the structure of the solar cell 10, we refer now to the final layer of the solar cell or module. In the embodiment of the invention shown in FIG. 1, the device is shown in the superstrate configuration, which means that the substrate material used during the deposition becomes the top (superstrate) window, and the various layers are deposited in order starting with the substrate layer 12. In other configurations the substrate material used during the deposition becomes the bottom layers, and the various layers are deposited in order starting with this substrate material. Therefore, for purposes of this invention, the term “substrate layer” means either a substrate or a superstrate.

In a preferred embodiment of the invention, the transparent electrode layer 14 is any one or more of the group zinc oxide (ZnO), zinc sulfide (ZnS), cadmium oxide (CdO), tin oxide doped with fluorine (SnO₂:F), indium oxide doped with tin (In₂O₃:Sn), gallium oxide (Ga₂O₃), combinations of the preceding and other well known compositions transparent conductive coatings comprised of metal dielectric layers. Most preferably, the transparent electrode layer 14 is ZnO. Also, preferably, the transparent electrode layer 14, whether ZnO, ZnS or CdO, and is doped with a Group III element to form an n-type semiconducting layer. Most preferably, the transparent electrode layer 14 is ZnO doped with aluminum or SnO doped with fluorine. Layer 18 is a high resistivity transparent (HRT) layer which may be any one of the group specified for layer 14 but without doping so that the electrical resistance is high. Preferably this HRT layer is ZnO or SnO₂ with thickness of about 25 nm to about 200 nm; most preferably with a thickness from about 50 nm to about 100 nm.

The first of two primary semiconductor layers, together forming an active semiconductor junction 30, is an n-type semiconductor layer 20. In a preferred embodiment of the invention this n-type semiconductor layer 20 is cadmium sulfide (CdS). The second primary semiconductor layer is a p-type semiconductor 22, which is preferably cadmium telluride (CdTe) or an alloy of CdTe. Numerous other semiconductor layers can be used for either of these two primary semiconductor layers, as will be appreciated by those skilled in the art. It is to be understood that an intrinsic semiconductor layer, not shown, can be disposed between the n-type semiconductor layer and the p-type semiconductor layer in conjunction with the present invention.

An optional layer of back buffer material is indicated at 24. Typically, this layer may be CdTe heavily doped with copper or a layer of tellurium formed by chemical etching of CdTe or a layer of ZnTe doped with Cu or ZnTe doped Cu with N. The back buffer layer 24 acts to provide an interface between the p-type semiconductor layer 22 and a back conductive electrode layer 26, which is the second of the two ohmic contacts or electrodes for the photovoltaic cell 10. The conductive back electrode layer 26 contains a conductive lead 28 for conducting current through the electric circuit, not shown. Typically, the conductive electrode layer is made of nickel, titanium, chromium, aluminum, gold or some other conductive material. Optionally, an additional protective or buffer layer 24 of zinc telluride, not shown, can be positioned between the back contact layer 26 and the cadmium telluride semiconductor layer 22 to facilitate hole (positive charge carrier) transport from the cadmium telluride layer to the back electrode layer and to protect the cadmium telluride layer form foreign contamination by migration. Also, it is to be understood that the layer 24 of back buffer material and the back electrode layer 26 can sometimes be combined into a single layer, not shown. To handle both functions in a single contacting layer, the single layer would have to have an electrical conductivity substantially equivalent to that of the back electrode layer 26, and yet still would have to be capable of making good transition to the CdTe semiconductor layer.

The photovoltaic cell 10 includes a substrate layer 12, which preferably is a glass substrate 12. Other transparent materials, such as polyimides, can be used for the glass substrate 12. A layer of a transparent conductive material, such as a transparent electrode layer 14, is applied to the glass layer 12. The transparent electrode layer 14 forms one of the two ohmic contacts or electrodes for the photovoltaic cell 10, and contains a conductive lead 16 for conducting current through an electric circuit, not shown. The transparent electrode layers are also sometimes referred to as a transparent conductive oxide, although some useful materials for this purpose are not oxides.

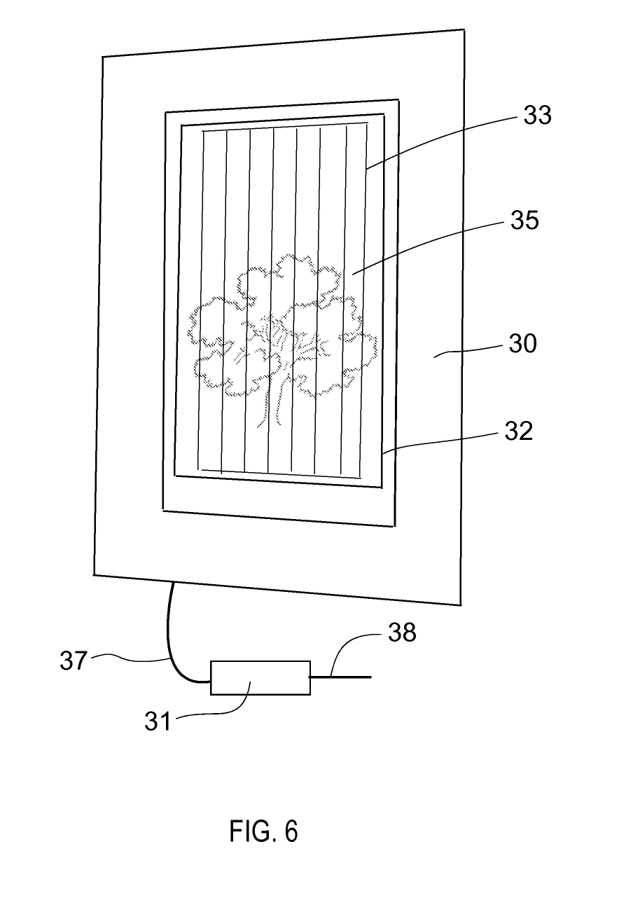

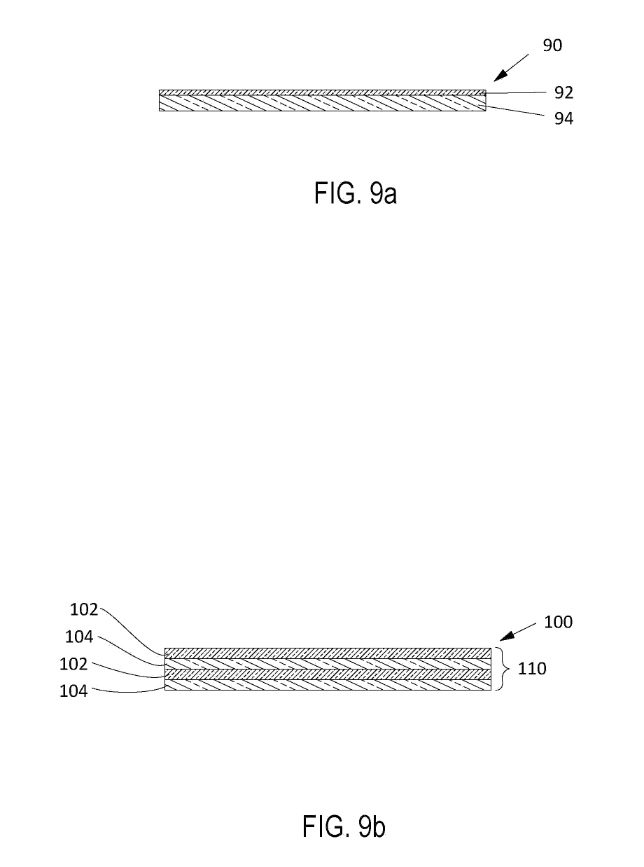

This back contact (BC) 26 must have suitable electronic characteristics as required for a back contact to CdTe and it must be transparent. Among the required electronic properties are that the work function must be a good match to the electron affinity of the CdTe layer 22 such that the positive charge carriers (holes) can flow readily into the BC. The embodiment of BC preferred in the prototype window unit that is shown in FIGS. 6 and 9 is a very thin layer 92 of Cu and a thin layer 94 of Au followed by the deposition of a transparent conductor 95 such as ZnO:Al or indium tin oxide (ITO). These layer thicknesses are preferred to be in the ranges of: for Cu: 0.2 nm to 3 nm; for Au: 3 nm to 30 nm; and for the transparent conducting oxide (e.g., AZO or ITO): 500 to 1500 nm. This final BC layer most preferably should be adjusted in thickness such that optical interference effects result in light wavelengths reflected back into the CdTe that are most effective in power generation. For example, this includes the near infrared region with little or no eye sensitivity, roughly in the range from about 600 nm to 850 nm. And the thickness should most preferably also be adjusted so that light in the more sensitive range of the eye should have minimal reflection from the back contact, e.g., from 450 to 600 nm. Similar considerations can apply to adjustments of the thicknesses of all the layers. The goal is to maximize the absorption of light in the most sensitive power-generating range of the CdTe cell and otherwise maximize the transmission of light visible to the eye. Thickness adjustments can also be used to help balance the color neutrality of the transmitted light.

The embodiment of BC preferred in FIG. 9b is one or more pair of layers 110 of a thin metal 102 and a dielectric 104 such as Ag/SiO₂ or Ag/SiO₂/Ag/SiO₂. Other metals such as Au, Ni, Cu, Al may be used and other dielectrics such as TiO₂, SnO₂, MgO, and ZnO may be used. The layer thicknesses will be adjusted to produce good optical transmissions from about 450 nm to about 600 nm and high reflection for wavelengths above about 600 nm. The high reflection in the region of about 600 nm to 850 nm corresponds to a region of high quantum efficiency for CdS/CdTe solar cells so that reflecting this transmitted light back into the cell structure will enhance the cell efficiency but will hardly affect the perception of transparency of the PV window by the human eye. Thickness adjustments can be used to help shift the transition from transmission to high reflection to balance the transmitted light color neutrality, for example by reflecting more of the red or yellow light in the region from about 550 nm to about 600 nm.

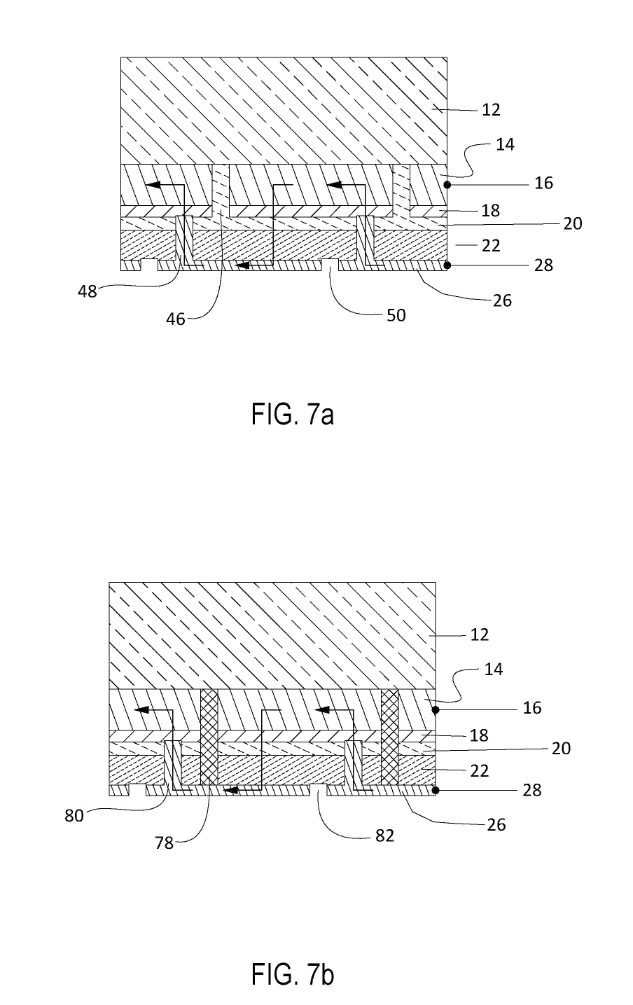

Monolithic integration is an important part of fabricating a large-area module 32 that is suitable for window applications 30. The illustration of FIG. 6 shows vertical lines 33 that are three-scribe interconnects that provide monolithic series connection for, in this case. 13 cell strips 35. This integrates the cells into a module with a voltage that is 13 times the individual cell voltage and current equal to the individual cell current. Two options for the structure of the three-scribe interconnect are shown in FIGS. 7a and 7b. In case 7a the scribes 46, 48, 50 are made sequentially during the thin-film deposition process. P1 scribe 46 occurs before the deposition of CdS and CdTe. The P2 scribe 48 occurs after but before the back contact. The P3 scribe 50 occurs after the back contact. In case 7b, scribes P1 and P2 78, 80 are made after the deposition of CdS and CdTe with an insulating backfill 49 added to the P1 scribe 78 before the BC. The P3 scribe 82 is made after the BC. A third option for the scribed interconnect is to do all three scribes after the BC is deposited. In this case P1 must be backfilled with an insulating material and P2 is filled with a conducting material that also covers the P1 insulating material 47 to provide electrical continuity up to the P3 scribe. It should be noted that scribe patterning can be done along the long dimension of the module or along the short dimension of the module and also with the width of the cells adjusted to provide voltage outputs most suited for any particular application.

As shown in FIG. 6 a battery pack 31 can be connected to the PV module 32 in a window 30 or other suitable application for such a PV module. A wire 37 connects the battery pack 31 to the module 32. The battery pack provides local storage of the DC voltage generated by the PV module. An electrical lead 38 extends from the battery pack to allow the stored DC voltage to be used by DC devices.

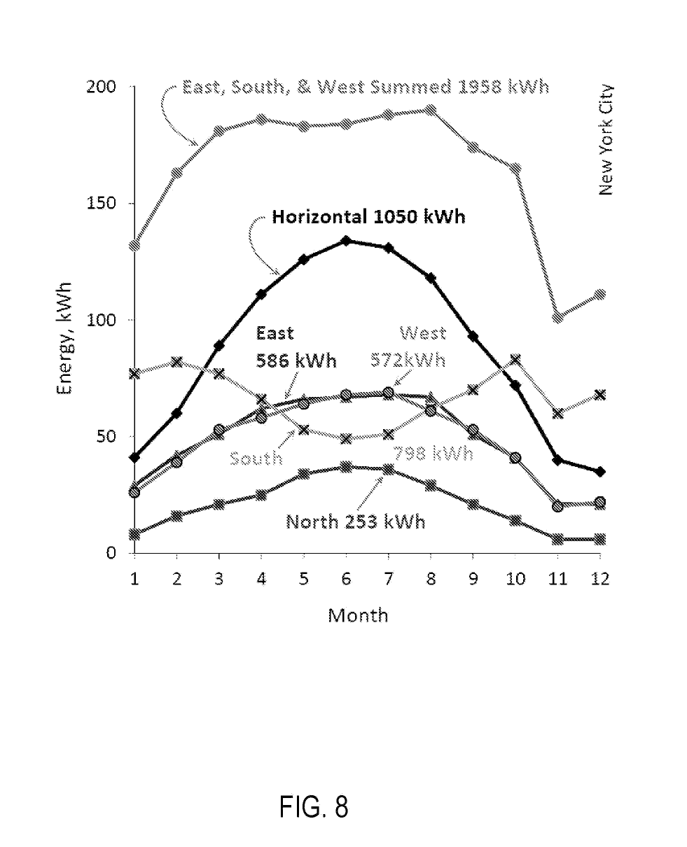

The potential performance for such semitransparent modules when implemented in buildings is shown in FIG. 8. These modeling data show that the vertically oriented windows can provide substantial amounts of electricity generation for most locations, illustrated here for New York City. South-facing windows are best but east and west-facing windows also provide excellent generation and even north-facing windows deliver 25% of the energy of rooftop arrays.

Additional features of the preferred embodiment include a process step involving activation with heat treatments of vapors of CdCl₂. It may also include a suitable process for shunt passivation and the blocking of occasional pinholes using well-known steps of negative photoresists or other processes. This passivation step is preferably done after the activation step and before the application of the back contact. It may also involve the incorporation of a high resistance buffer layer between the CdTe and the BC.

For use as a window PV generation device, it may be desired to include an integral micro-inverter on each window or module to provide AC power out from the PV window that is suitable for integration into the home or business electrical system, typically 110 V or 220 V for the U.S. This AC power output can facilitate a “plug-and-play” installation in buildings.

The above detailed description of the present invention is given for explanatory purposes. It will be apparent to those skilled in the art that numerous changes and modifications can be made without departing from the scope of the invention. Accordingly, the whole of the foregoing description is to be construed in an illustrative and not a limitative sense, the scope of the invention being defined solely by the appended claims.

We claim:

1. A thin-film photovoltaic (PV) cell that is intrinsically semitransparent that generates solar electricity and transmits visible light, comprising:
a transparent substrate or superstrate layer, such as glass or polymer such as a polyimide;
a transparent conducting layer, such as a transparent conducting oxide
a semiconducting structure with an n-p junction or an n-i-p junction that absorbs a wide range of light wavelengths and generates current and voltage; and
a substantially transparent back contact (BC) structure that transmits visible light and conducts current.

2. The PV cell of claim 1 wherein the BC structure has thicknesses and compositions to optimally reflect certain wavelengths of light back into the semiconductors and optimally transmit other wavelengths through the device.

3. The PV cell of claim 1 wherein interfacial buffer layers are positioned between the TCO and semiconductors and/or between the semiconductors and the BC, these layers are chosen to reduce the effects of any pinholes or weak diodes on the performance of the cell or module and to adjust the energy band alignments to facilitate electron and hole transport across interfaces.

4. The PV cell of claim 2 wherein the BC comprises very thin layers of copper, thin layers of gold, alloys of copper, alloys of gold and combinations thereof, such layers being transparent.

5. The PV cell of claim 4 wherein the BC includes a transparent conductive layer such as a TCO.

6. The PV cell of claim 4 wherein the thickness of the copper is from about 0.2 nm to about 3.0 nm and the thickness of the gold is from about 3 nm to about 30 nm.

7. The PV cell of claim 4 wherein the BC includes layers selected from silver, nickel, aluminum and titanium.

8. The PV cell of claim 1 wherein the semiconductors are CdS, CdTe and alloys of CdTe such as CdZnTe.

9. The PV cell of claim 1 wherein the back contact comprises one or more metallic and dielectric layers to produce a transparent conducting layer in which the metal may be Ag and the dielectric may be SiO₂.

10. The PV cell of claim 9 wherein the silver-based transparent layer has a thickness from about 3 nm to about 30 nm.

11. The PV cell of claim 1 wherein the structure of the PV cell of claim incorporates monolithic integration to connect individual cell strips of substantially equal area into a series integration such that the output voltages of the individual cells add.

12. The PV cell of claim 11 wherein an inverter is incorporated to provide power output at an AC voltage, the inverter may be on the PV cell or otherwise incorporated into the window, skylight, canopy, or other structure incorporating the PV cell.

13. The PV cell of claim 11 wherein a battery pack is connected off grid to the PV cell to provide local storage of a DC voltage generated by the PV cell, the DC voltage from the battery pack is available for use by DC powered devices.

14. The PV cell of claim 11 wherein a second pane of glass and a sealing mechanism is provided to form the PV cell into an insulated window unit (IGU).

15. The PV cell of claim 11 wherein a flexible polymer which incorporates suitable encapsulation to remain flexible and transparent, and still provides protection from moisture and oxygen is used as a substrate/superstrate.

16. A method of fabricating a thin-film photovoltaic cell that is intrinsically semitransparent, generates electricity and transmits visible light comprising:
providing a transparent substrate;
depositing an active polycrystalline semiconductor junction having an n-type layer and a p-type layer onto the transparent substrate under process conditions that avoid substantial degradation of the electrode layer, in which the depositing of the n-type layer and the p-type layer is carried out with a sputtering process; the p-type layer having a thickness of less than 750 nm; and
applying a semitransparent back electrode layer to form a diode structure.

17. The method of claim 16 in which the sputtering process is carried out at a temperature range from about 150° C. to about 350° C.

18. The method of claim 16 in which the sputtering process is carried out at a temperature less than 250° c.

19. The method of claim 16 in which a back contact layer is applied to the polycrystalline layer by a sputtering process.

20. The method of claim 16 in which the semitransparent back electrode layer can include one or more transparent conductive materials with appropriate doping elements.

21. The method of claim 16 in which a transparent electrode layer of any one or more of the group ZnO, ZnS, CdO, SnO₂ and In₂O₃ is deposited onto the transparent substrate.

22. The method of claim 16 in which the transparent electrode layer and/or the semitransparent back electrode layer can include transparent multilayer ultra-thin metal coatings, such as Ag, Au, Cu, Al, Ni which are electrically conducting.

23. The method of claim 21 in which a very thin high resistivity transparent (HRT) layer of any one or more of the group ZnO, ZnS, CdO, SnO₂ and In₂O₃ is deposited on the transparent electrode layer.

24. The method of claim 23 in which the HRT layer can include materials that are without intentional doping, highly resistive and optically transparent.

25. The method of claim 16 in which a high resistivity interfacial layer, preferably an HRT layer which is p-type such as ZnTe with optionally small dopant densities of N or Cu is applied to the back electrode layer.

26. The method of claim 16 in which the sputter process is carried out at a sputter gas pressure in the range from about 3 mTorr to about 50 mTorr and the sputter distance is from about 15 cm to about 5 cm.

27. The method of claim 25 in which the sputter gas pressure is preferably in the range from about 5 mTorr to about 15 mTorr.
